(19) United States
(12) Patent Application Publication
(10) Pub. No.: US 2004/0126962 A1
(43) Pub. Date: Jul. 1, 2004

(54) [METHOD OF FABRICATING SHALLOW TRENCH ISOLATION]

(76) Inventors: Szu-Tsun Ma, Hsinchu (TW); Kent Kuohua Chang, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/249,787

(22) Filed: May 8, 2003

(30) Foreign Application Priority Data
Dec. 25, 2002 (TW) 91137266

(51) Int. Cl. H01L 21/8242

(52) U.S. Cl. 438/248

(57) ABSTRACT

A method of fabricating a shallow trench isolation. A wafer on which a mask layer is formed is provided. A blank wafer is provided and disposed in an etching machine to perform an etching process. Whether the blank wafer contains a defect is inspected. If the number of defects occurring on the blank wafer is within an acceptable quantity, the wafer is disposed in the etching machine for performing an etching process and defining a trench. The trench is then filled with an insulation layer. The mask layer is removed to form a shallow trench isolation.

### CROSS REFERENCE TO RELATED APPLICATIONS

This application claims the priority benefit of Taiwan application serial no. 91137266, filed Dec. 25, 2002.

### BACKGROUND OF INVENTION

1. Field of the Invention

The invention relates in general to a shallow trench isolation (STI), and more particularly, to a method of monitoring and controlling defects for a shallow trench isolation process.

2. Related Art of the Invention

The shallow trench isolation process is a technique for forming an isolation of a device by anisotropic etching a semiconductor substrate to form a trench therein, followed by filling the trench with oxide. The isolation formed by shallow trench isolation process has the scalable advantage. Further, the bird's beak encroachment formed by local oxidation technique can be avoided. Therefore, for sub-micron metal-oxide semiconductor (MOS) process, the shallow trench isolation is a relatively ideal isolation technique.

In the current shallow trench isolation process, island defect often occurs in the trench defined in the substrate. As the island defect and the substrate are both silicon material, and the island defect exists in the shallow trench isolation, such that the isolation performance of the shallow trench isolation is affected. When such island defect occurs near the edge of the trench, device current leakage is easily caused.

Therefore, an inspection step for confirming whether the island defect exists is performed after the trench is defined. In the conventional method of monitoring and controlling the defect during the shallow trench isolation process, a photoresist layer is formed on a blank wafer and an etching process is performed on the wafer. Then, the quantity of difference between the inspected defect levels before and after the process is used for a judgement.

Therefore, many drawbacks exist in the conventional inspection method for inspecting the number of island defects occurring in the trench. Since it has the poor capability to inspect the defect on the blank wafer coated with the photoresist, the actual number of island defects resulting from the etching process can not be precisely shown. As a result, the fabrication defects cannot be well controlled, and it cannot be achieved the function to automatically inspect the machine.

### SUMMARY OF INVENTION

The present invention provides a method of fabricating a shallow trench isolation to resolve the problem of producing island defect during the fabrication process.

The present invention further provides a method of fabricating a shallow trench isolation to improve the drawbacks of inability to find out the reason causing the island defect of the conventional inspection method.

In the method of fabricating a shallow trench isolation provided by the present invention, a wafer on which a mask layer is formed is provided. A blank wafer is further provided and disposed in an etching machine for performing an etching process. The blank wafer means that no photoresist layer, mask layer or other material layer is formed thereon. The etching process includes an etching reaction step and a cleaning step. After the etching step, the blank wafer is inspected to determine whether any defect is produced thereon. In the present invention, the defect inspection of the blank wafer includes using a dark field inspection or a bright field inspection. In addition, a first scanning step may be performed on the blank wafer before performing the etching process, and a second scanning step may be performed on the blank wafer after performing the etching process. The results of the first scanning step and the second scanning step are compared to determine the number of defects on the blank wafer. If the number of defects on the wafer is less than a setting quantity, then the wafer is shifted to the etching machine for performing etching process and defining the trench. The trench is then filled with an insulation layer, and the mask layer is removed to form the shallow trench isolation.

The present invention further provides a defect control method during a shallow trench isolation process. A product wafer and a blank wafer are provided. Before disposing the product wafer in an etching machine for performing an etching process, the blank wafer is disposed in the etching machine for performing an etching process. The etching process includes an etching reaction step and a clean step. The blank wafer is scanned to inspect whether defect is produced during the etching process. In the present invention, a dark field or a bright field inspection method is used to determine whether defect is produced. In addition, a first scanning step may be performed on the blank wafer before performing the etching process, and a second scanning step may be performed on the blank wafer after performing the etching process. The results of the first scanning step and the second scanning step are compared to determine whether defect is produced on the blank wafer. If the number of defect on the wafer is less than a setting quantity, then the wafer is shifted to the etching machine for performing etching process and defining the trench. The trench is then filled with an insulation layer, and the mask layer is removed to form the shallow trench isolation.

In the fabrication method of the shallow trench isolation, whether or not the etching machine is abnormal is confirmed with the number of defects having occurred before the trench is defined, such that the condition of producing island defect is improved.

Further, before performing etching process on the wafer, the blank wafer is used to inspect the condition of the etching machine. If defect is inspected in the blank wafer, the operator can thus exclude the defect causing factor of the machine.

In addition, as the blank wafer is used for performing inspection, the present invention will not cause loss of product wafers.

By using the blank wafer for inspection, the product wafer which has been processed will not be wasted should defect be produced due to an abnormal condition of the machine. As a result, the inspection method is simplified, and the cost is reduced.

### BRIEF DESCRIPTION OF DRAWINGS

These, as well as other features of the present invention, will become more apparent upon reference to the drawings.

FIG. 1 shows a process flow for forming a shallow trench isolation according to one embodiment of the present invention.

### DETAILED DESCRIPTION

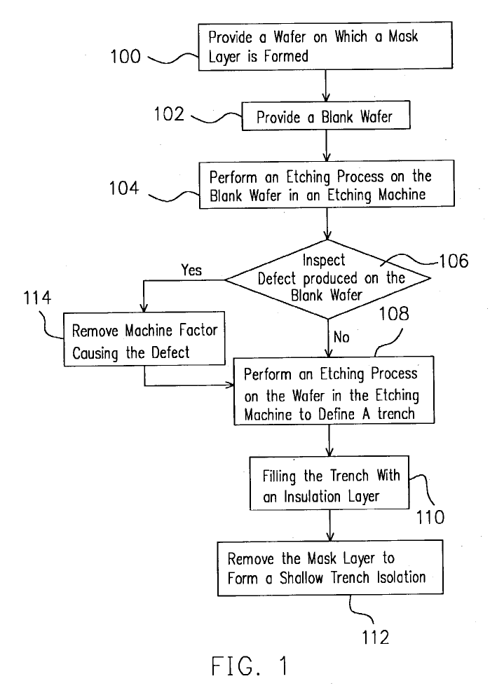

Referring to FIG. 1, a process flow for forming a shallow trench isolation according to one embodiment of the present invention is shown.

In FIG. 1, a wafer is provided (step 100). The wafer is referred as a product wafer, on which a mask layer is formed as an etching mask for the subsequent patterning process. In this embodiment, a pad oxide layer may further be formed between the mask layer and the wafer for protecting the surface of the wafer. The material of the mask layer includes silicon nitride, for example.

Meanwhile, a blank wafer is also provided (step 102). The blank wafer does not include a photoresist layer, a mask layer or any other material layer thereon.

Before performing an etching process for defining a trench on the wafer, the blank wafer is disposed in an etching machine, and an etching process is performed thereon (step 104). The etching process includes an etching reaction step and a cleaning step. After the etching process, whether the blank wafer contains any defect thereon is inspected (step 106). In other words, whether pillar or protrusion is produced on the blank wafer is inspected.

In this embodiment, the method of inspecting defect on the blank wafer includes dark field inspection or bright field inspection. In addition, the defect inspection method further includes a first scanning step and a second scanning step before and after performing the etching process on the blank wafer, respectively. The results of the first and the second scanning steps are compared to each other to determine the number of defects occurring on the blank wafer.

During the etching process performed on the blank wafer in the etching machine, if the surface of the blank wafer is not contaminated by a particle from the etching machine, a flat and uniform surface of the blank wafer results after the etching process. However, if the contamination particle is attached to the surface of the blank wafer, due to the etching rate differential between the wafer and the contamination particle, island defect such as pillar or protrusion is produced on the blank wafer after the etching process. Therefore, performing etching process and defect inspection on the blank wafer in advance may exclude the defect caused by etching machine.

Further referring to FIG. 1, in step 106, if no defect is inspected on the blank wafer, the step 108 is performed. That is, the wafer is disposed in the etching machine, and an etching process is performed to define a trench therein. Meanwhile, the island defect caused by the etching machine is prevented.

In step 110, an insulation layer is filled in the trench. The material of the insulation layer includes silicon nitride, for example, and the method for filling the insulation layer includes a global deposition, followed by an etch back or chemical mechanical polishing process until the mask layer is exposed.

Referring to FIG. 1, if a defect is inspected on the blank wafer in step 106, step 114 is performed. That is, the factor causing the defect by the machine has to be solved. In other words, when island defect is produced on the blank wafer, it indicates that the etching machine includes a contamination particle attached to the surface of the blank wafer during etching process. The etching machine is thus adjusted immediately to remove the contamination particle. After the contamination particle is removed from the etching machine, step 108 is performed. The wafer (that is, the product wafer) is disposed in the etching machine to define a trench therein. Step 110 is then performed to fill the trench with an insulation layer, followed by the step 112 that removes the mask layer to form the shallow trench isolation.

In the above method for fabricating the shallow trench isolation, a blank wafer is used to determine the status of defects occurring in the etching machine, such that it can be improve for the ability to inspect the problem of producing island defect with respect to the trench.

As the abnormality of the etching machine is inspected by etching a blank wafer before the actual etching process is performed, the operator can exclude such factor on the etching machine when the defect occurring on the blank wafer is exceed the setting quantity.

As the present invention uses a blank wafer to replace the product wafer for performing inspection, no loss of product wafer is caused.

As the defect inspection is not performed on the product wafer. The blank wafer is not necessary to go through the whole actual fabrication processes, and therefore the cost is reduced.

Other embodiments of the invention will appear to those skilled in the art from consideration of the specification and practice of the invention disclosed herein. It is intended that the specification and examples to be considered as exemplary only, with a true scope and spirit of the invention being indicated by the following claims.

1. A method of fabricating a shallow trench isolation, comprising:
providing a wafer that comprises a mask layer thereon;
providing a blank wafer;
disposing the blank wafer in an etching machine to perform an etching process thereon;
inspecting a quantity of defects occurring on the blank wafer after the etching process;
disposing the wafer in the etching machine to perform an etching process thereon when the quantity of the defects on the blank wafer is less than a setting quantity;
filling the trench with an insulation layer; and
removing the mask layer to form a shallow isolation trench.

2. The method according to claim 1, wherein the blank wafer does not comprise any layer formed thereon.

3. The method according to claim 1, wherein a dark field inspection method is used to inspect the quantity of the defects occurring on the blank wafer.

4. The method according to claim 1, wherein a bright field inspection method is used to inspect the quantity of the defects occurring on the blank wafer.

5. The method according to claim 1, wherein the step of inspecting the quantity of the defects occurring on the blank wafer further comprises performing a first scanning step on the blank wafer before performing the etching process thereon; performing a second scanning step on the blank wafer after performing the etching process thereon; and comparing results of the first and second scanning steps to determine the quantity of the defects.

6. The method according to claim 1, wherein the mask layer is made of silicon nitride.

7. The method according to claim 1, further comprising a step of forming a pad oxide between the mask layer and the substrate.

8. The method according to claim 1, wherein the insulation layer is made of silicon oxide.

9. The method according to claim 1, wherein the etching step performed on the blank wafer further comprises an etching reaction step and a cleaning step.

10. A method of monitoring and controlling defect during a shallow isolation trench process, comprising:
providing a product wafer and a blank wafer;
disposing the blank wafer and the product wafer in an etching machine to perform an etching process thereon;
scanning the blank wafer to inspect a quantity of defects occurring on the blank wafer; and
disposing the product wafer in the etching machine to perform an etching process and define a trench therein when the quantity of the defects is less than a setting quantity.

11. The method according to claim 10, wherein the blank wafer does not comprise any layer formed thereon.

12. The method according to claim 10, wherein a dark field inspection method is used to inspect the quantity of the defects occurring on the blank wafer.

13. The method according to claim 10, wherein a bright field inspection method is used to inspect the quantity of the defects occurring on the blank wafer.

14. The method according to claim 10, wherein the step of scanning the blank wafer further comprises performing a first scanning step on the blank wafer before performing the etching process thereon; performing a second scanning step on the blank wafer after performing the etching process thereon; and comparing results of the first and second scanning steps to determine the quantity of the defects.

15. The method according to claim 10, wherein the etching step performed on the blank wafer further comprises an etching reaction step and a cleaning step.
